(19) United States
(12) Patent Application Publication
(10) Pub. No.: US 2015/0228756 A1
(43) Pub. Date: Aug. 13, 2015

(54) SEMICONDUCTOR DEVICE AND METHOD OF MANUFACTURING THE SAME

(71) Applicant: Mitsubishi Electric Corporation, Chiyoda-ku (JP)

(72) Inventors: Kenichiro KURAHASHI, Tokyo (JP); Takuma Nanjo, Tokyo (JP); Muneyoshi Suita, Tokyo (JP); Yosuke Suzuki, Tokyo (JP); Akifumi Imai, Tokyo (JP); Marika Nakamura, Tokyo (JP); Eiji Yagyu, Tokyo (JP)

(73) Assignee: Mitsubishi Electric Corporation, Chiyoda-ku (JP)

(21) Appl. No.: 14/611,757

(22) Filed: Feb. 2, 2015

(30) Foreign Application Priority Data
Feb. 12, 2014 (JP) 2014-023948
Dec. 3, 2014 (JP) 2014-244629

(51) Int. Cl. H01L 29/66; H01L 29/20; H01L 21/324; H01L 29/205; H01L 29/47; H01L 21/283; H01L 29/778; H01L 29/201

(52) U.S. Cl. CPC H01L 29/66462; H01L 29/7787; H01L 29/2003; H01L 29/201; H01L 29/205; H01L 29/475; H01L 21/283; H01L 21/324

(57) ABSTRACT

A semiconductor device includes an Alₓ₁Ga₁₋ₓ₁N (0≦x1≦1) barrier layer, and a gate electrode that is disposed on a surface of the Alₓ₁Ga₁₋ₓ₁N (0≦x1≦1) barrier layer, forms a Schottky junction with the surface of the Alₓ₁Ga₁₋ₓ₁N (0≦x1≦1) barrier layer, and has an Ni single-layer structure. Annealing processing is performed with respect to the gate electrode at a temperature of 500° C. or above under a nitrogen atmosphere to form a reaction layer between the surface of the Alₓ₁Ga₁₋ₓ₁N (0≦x1≦1) barrier layer and the gate electrode.

### BACKGROUND OF THE INVENTION

1. Field of the Invention

The present invention relates to a semiconductor device that includes a gate electrode forming a Schottky junction, and a method of manufacturing the semiconductor device.

2. Description of the Background Art

In a semiconductor device that includes a Schottky gate electrode (a gate electrode forming a Schottky junction), it is desirable to reduce reverse leakage currents, for example, by increasing the height of a Schottky barrier at a Schottky junction between a gate electrode and a surface of a semiconductor layer. A nitride semiconductor field-effect transistor typified by an Alₓ₁Ga₁₋ₓ₁N (0≦x1≦1)/GaN heterojunction structure typically has an Ni/Au electrode structure in which an Au layer is stacked on an Ni layer, and a gate electrode structure including the Ni/Au electrode structure as a base. In a process of manufacturing such a transistor, annealing processing performed at a temperature of approximately 500° C. or similar processing is sometimes added as a Schottky gate electrode formation process in order to increase the height of a Schottky barrier, and thereby to reduce reverse leakage currents (gate leakage currents), i.e., to improve electrical characteristics (e.g., Japanese Patent Application Laid-Open No. 2009-238956, Japanese Patent Application Laid-Open No. 2004-87587, and Fumio Hasegawa, Akihiko Yoshikawa, Wide Gap Semiconductors, Optical and Electron Devices, Morikita Publishing Co., Ltd., 2006, p. 244-245). High-temperature annealing processing performed with respect to an electrode at a temperature above 500° C., however, is commonly used not as a means to reduce reverse leakage currents, but as a means to provide an ohmic contact (an ohmic junction) (e.g., Fumio Hasegawa, Akihiko Yoshikawa, Wide Gap Semiconductors, Optical and Electron Devices, Morikita Publishing Co., Ltd., 2006, p. 244-245, and Japanese Patent Application Laid-Open No. 2009-231395).

As described above, high-temperature annealing processing performed with respect to a Schottky junction at a temperature of 500° C. or above leads not to a reduction but rather to an increase in reverse leakage currents (formation of an ohmic contact). In the process of manufacturing a nitride semiconductor field-effect transistor that includes a Schottky gate electrode, a process involving annealing processing performed at a temperature of 500° C. or above is therefore required to be performed before formation of the gate electrode, resulting in a problem in that an order of steps of the manufacturing method is restricted. That is to say, demands for suppression of reverse leakage currents and restrictions placed on the manufacturing method are problems to be solved.

### SUMMARY OF THE INVENTION

The present invention has been conceived in view of the above-mentioned problems, and aims to provide technology for reducing reverse leakage currents and increasing flexibility in the manufacturing method in semiconductor devices formed of nitride semiconductors.

One aspect of the present invention is a semiconductor device including: a semiconductor layer that is an Alₓ₁Ga₁₋ₓ₁N (0≦x1≦1) barrier layer or an Alₓ₂Ga₁₋ₓ₂N (0≦x2≦1) cap layer formed on the barrier layer; a gate electrode that is disposed on a surface of the semiconductor layer, and forms a Schottky junction with the surface of the semiconductor layer, at least a lowermost layer of the gate electrode substantially being Ni; and a reaction layer that is provided at an interface of the Schottky junction, and contains Ni of the lowermost layer of the gate electrode and an element contained in the semiconductor layer, but does not contain a metal element diffusing from a metal layer on or above Ni of the lowermost layer of the gate electrode.

Another aspect of the present invention is a method of manufacturing a semiconductor device, the method including the steps of: (a) forming a gate electrode on a surface of a semiconductor layer that is an Alₓ₁Ga₁₋ₓ₁N (0≦x1≦1) barrier layer or an Alₓ₂Ga₁₋ₓ₂N (0≦x2≦1) cap layer formed on the barrier layer, the gate electrode forming a Schottky junction with the surface of the semiconductor layer, and having an Ni single-layer structure; and (b), after the step (a), performing annealing processing with respect to the gate electrode at a temperature of 500° C. to 750° C. inclusive under a nitrogen atmosphere to form a reaction layer between the surface of the semiconductor layer and the gate electrode, the reaction layer containing Ni of the gate electrode and an element contained in the semiconductor layer.

Reverse leakage currents can be reduced, and flexibility in the manufacturing method can be increased.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross section showing the structure of a semiconductor device according to Embodiment 1;

FIG. 2 is a plan schematic view of the semiconductor device according to Embodiment 1;

FIG. 3 is a flow chart showing a method of manufacturing the semiconductor device according to Embodiment 1;

FIGS. 4 and 5 are cross sections for describing the method of manufacturing the semiconductor device according to Embodiment 1;

FIG. 6 is a diagram for describing electrical characteristics of the semiconductor device according to Embodiment 1;

FIGS. 7 to 9 show an element ratio in a depth direction of a first sample;

FIG. 10 is a diagram for describing electrical characteristics of the semiconductor device according to Embodiment 1;

FIG. 11 is a flow chart showing a method of manufacturing a semiconductor device according to Embodiment 2;

FIGS. 12 and 13 are cross sections for describing the method of manufacturing the semiconductor device according to Embodiment 2;

FIG. 14 is a flow chart showing a method of manufacturing a semiconductor device according to Embodiment 3;

FIG. 15 is a cross section for describing the method of manufacturing the semiconductor device according to Embodiment 3;

FIG. 16 is a cross section showing the structure of a semiconductor device according to Embodiment 4; and

FIG. 17 is a flow chart showing a method of manufacturing the semiconductor device according to Embodiment 4.

### DESCRIPTION OF THE PREFERRED EMBODIMENTS

### Embodiment 1

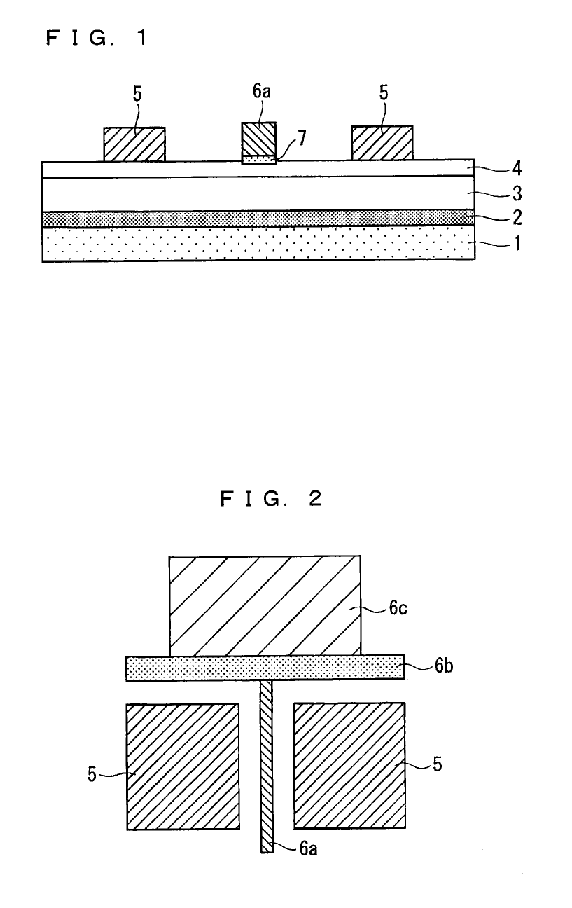

FIG. 1 is a cross section showing the structure of a semiconductor device according to Embodiment 1 of the present invention. The semiconductor device shown in FIG. 1 includes a semi-insulating SiC (silicon carbide) substrate 1, a buffer layer 2, a GaN channel layer 3, an Alₓ₁Ga₁₋ₓ₁N (0≦x1≦1) harrier layer 4, source and drain electrodes 5, and a gate electrode 6a. Al, Ga, and N represent aluminum, gallium, and nitrogen, respectively.

The buffer layer 2 at least includes a layer containing Al_{y1}Ga_{1-y1}N (0≦y1≦1), for example, and is disposed on the SiC substrate 1. The GaN channel layer 3 is disposed on the buffer layer 2. The Alₓ₁Ga₁₋ₓ₁N (0≦x1≦1) barrier layer 4 is a semiconductor layer formed of a nitride semiconductor, and is disposed on the GaN channel layer 3. The GaN channel layer 3 and the Alₓ₁Ga₁₋ₓ₁N (0≦x1≦1) barrier layer 4 are provided as semiconductor operation layers, and highly-concentrated carriers can be generated at an interface between the GaN channel layer 3 and the Alₓ₁Ga₁₋ₓ₁N (0≦x1≦1) barrier layer 4.

For the sake of simplicity, a typical structure including a substrate formed of SiC is described previously as an example of a layer structure of an epitaxial substrate including the Alₓ₁Ga₁₋ₓ₁N (0≦x1≦1) barrier layer, but a structure including a substrate formed of Si may be used as necessary. A double heterostructure in which an Al_{y2}Ga_{1-y2}N (0≦y2≦1) layer or the like is interposed between the buffer layer and the GaN channel layer may be adopted. Furthermore, a spacer layer formed of AlN may be interposed between the GaN channel layer and the Alₓ₁Ga₁₋ₓ₁N (0≦x1≦1) barrier layer, and a cap layer formed of Alₓ₂Ga₁₋ₓ₂N (0≦x2≦1) may be formed on the Alₓ₁Ga₁₋ₓ₁N (0≦x1≦1) barrier layer.

The source and drain electrodes 5 are disposed on a surface of the Alₓ₁Ga₁₋ₓ₁N (0≦x1≦1) barrier layer 4 (when an Alₓ₂Ga₁₋ₓ₂N (0≦x2≦1) cap layer is formed, the source and drain electrodes are disposed on the Alₓ₂Ga₁₋ₓ₂N (0≦x2≦1) cap layer). The source and drain electrodes 5 have ohmic electrode structures (are ohmic electrodes), and form ohmic contacts with the surface of the Alₓ₁Ga₁₋ₓ₁N (0≦x1≦1) barrier layer 4.

The gate electrode 6a is disposed, on the surface of the Alₓ₁Ga₁₋ₓ₁N (0≦x1≦1) barrier layer 4, between the source and drain electrodes 5. The gate electrode 6a has an Ni (nickel) single-layer structure. The gate electrode 6a forms a Schottky junction with the surface of the Alₓ₁Ga₁₋ₓ₁N (0≦x1≦1) barrier layer 4.

Annealing processing has been performed with respect to the gate electrode 6a at a temperature of 500° C. to 750° C. inclusive under a nitrogen atmosphere, so that a reaction layer 7 is formed between the above-mentioned surface of the Alₘ Ga₁₋ₓ₁N (0≦x1≦1) barrier layer 4 and the gate electrode 6a. That is to say, the reaction layer 7 is formed through reaction of the Alₓ₁Ga₁₋ₓ₁N (0≦x1≦1) barrier layer 4 and the gate electrode 6a at an interface of a Schottky junction (a contact interface) between the Alₓ₁Ga₁₋ₓ₁N (0≦x1≦1) barrier layer 4 and the gate electrode 6a. In Embodiment 1, the annealing processing is performed at a temperature of 500° C. to 750° C. inclusive.

FIG. 2 is a plan schematic view of the semiconductor device according to Embodiment 1 of the present invention. The semiconductor device shown in FIG. 2 includes a gate feeder 6b and a gate electrode pad 6c in addition to the source and drain electrodes 5 and the gate electrode 6a. In order to operate the semiconductor device shown in FIG. 2 as a transistor, it is required to control currents between the source and drain electrodes 5 by applying potential as an input signal to the gate electrode pad 6c, and eventually to the gate electrode 6a through the gate feeder 6b electrically connected to the gate electrode pad 6c. This means that Embodiment 1 is technology that is mainly targeted at the gate electrode 6a into which a reverse leakage current can flow, and is not technology that is mainly targeted at the gate feeder 6b and the gate electrode pad 6c. Therefore, in explanation/description of the structure according to the present invention and the method of manufacturing the structure, the gate electrode 6a, the gate feeder 6b, and the gate electrode pad 6c are distinguished from one another.

<Manufacturing Method>

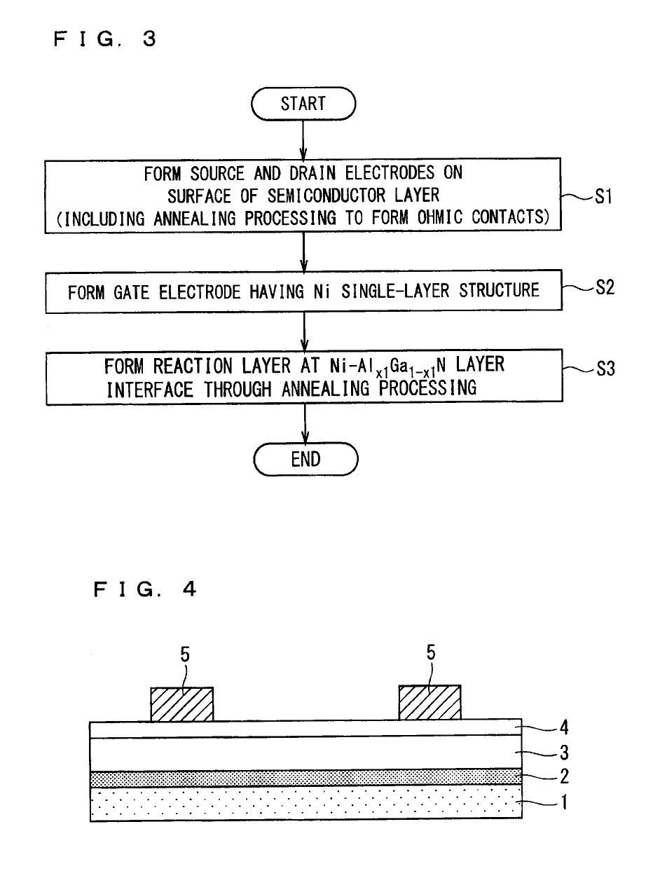

FIG. 3 is a flow chart showing a method of manufacturing the semiconductor device according to Embodiment 1. The method of manufacturing the semiconductor device is described below, in an order of steps shown in FIG. 3.

In step S1, as shown in FIG. 4, the buffer layer 2, the GaN channel layer 3, and the Alₓ₁Ga₁₋ₓ₁N (0≦x1≦1) barrier layer 4 are formed on the SiC substrate 1 in the stated order. These semiconductor layers are formed by an epitaxial growth method, for example.

In the same step S1, electrodes that become the source and drain electrodes 5 are then formed in regions, on a surface of the Alₓ₁Ga₁₋ₓ₁N (0≦x1≦1) barrier layer 4, other than a region in which the gate electrode 6a is to be formed. Annealing processing is then performed to form, from the electrodes, the source and drain electrodes 5 (ohmic electrodes) that form ohmic contacts with the surface of the Alₓ₁Ga₁₋ₓ₁N (0≦x1≦1) barrier layer 4.

In Embodiment 1, the electrodes that become the source and drain electrodes 5 have Ti/Al/Ti/Au (having thicknesses of 20 nm, 100 nm, 40 nm, and 30 nm, respectively) ohmic electrode structures. The source and drain electrodes 5, however, are not limited to the electrodes having the Ti/Al/Ti/Au electrode structures as long as their electrode structures (electrodes) can provide ohmic contacts with the Alₓ₁Ga₁₋ₓN (0≦x1≦1) barrier layer 4, and may have Ti/Al/Ni/Au electrode structures, Ti/Al/Nb/Au electrode structures, or electrode structures (electrodes) other than Ti/Al series electrode structures, for example. Ti, Au, and Nb represent titanium, gold, and niobium, respectively.

In Embodiment 1, the electrodes that become the source and drain electrodes 5 are formed by a deposition lift-off method using a resist pattern having a double-layer structure. However, other methods (e.g., a sputter lift-off method, a combination of the deposition lift-off method and the sputter lift-off method, and a method of eliminating unnecessary metal through etch back after sputtering) may be used as long as desired ohmic contacts can be provided.

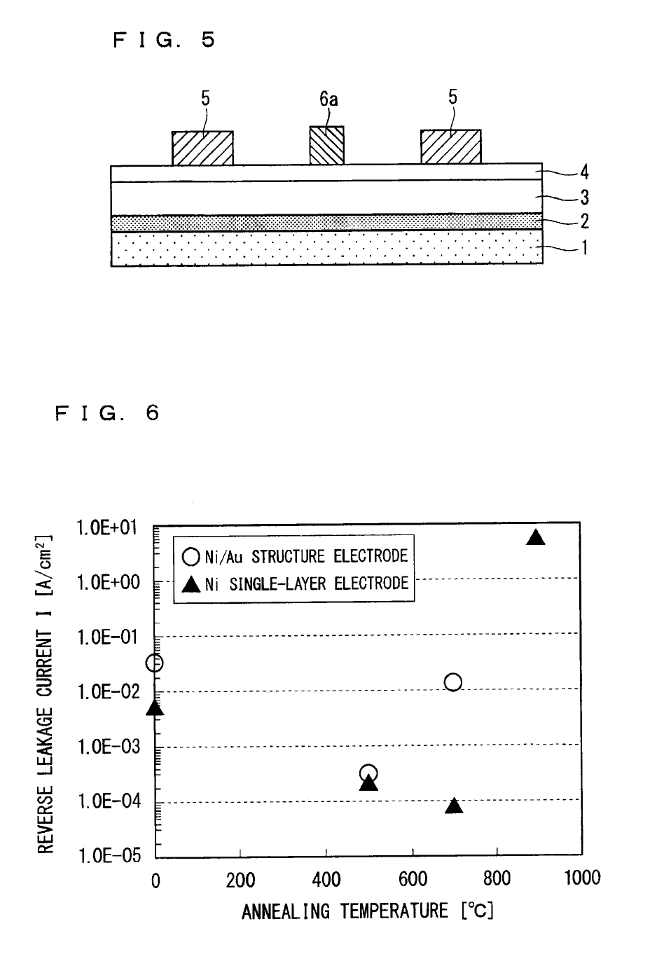

Next, in step S2, as shown in FIG. 5, the gate electrode 6a that forms a Schottky junction with the surface of the Alₓ₁Ga₁₋ₓ₁N (0≦x1≦1) barrier layer 4 and has the Ni single-layer structure is formed on the surface of the Alₓ₁Ga₁₋ₓ₁N (0≦x1≦1) barrier layer 4.

In Embodiment 1, the thickness of the gate electrode 6a in its height direction is 200 nm, but the gate electrode 6a may have any other thickness as long as the gate electrode 6a functions as a Schottky gate electrode. In Embodiment 1, the gate electrode 6a is formed by the deposition lift-off method using a resist pattern having a double-layer structure. However, other methods (e.g., the sputter lift-off method, the combination of the deposition lift-off method and the sputter lift-off method, and the method of eliminating unnecessary metal through etch back after sputtering) may be used as long as the gate electrode 6a having the Ni single-layer structure can be formed.

Next, in step S3, annealing processing is performed with respect to the gate electrode 6a at a temperature of 500° C. or above under a nitrogen atmosphere. Conditions of the annealing processing are that the annealing processing is performed at a temperature of 500° C. to 750° C. inclusive for five minutes under an inert gas atmosphere, for example. The annealing processing is preferably performed at a temperature of 700° C. for five minutes under an N₂ atmosphere. As a result, as shown in FIG. 1, the reaction layer 7 is formed between the above-mentioned surface of the Alₓ₁Ga₁₋ₓ₁N (0≦x1≦1) barrier layer 4 and the gate electrode 6a, and the semiconductor device according to Embodiment 1 is completed. According to the semiconductor device produced as described above, reverse leakage currents per unit area in reverse applied voltages are suppressed as described below.

<Effects>

FIG. 6 shows a relation between temperature of annealing processing and reverse leakage currents for the Schottky gate electrode. Although reverse leakage currents have negative values, description is made herein on the absolute values thereof.

White circles indicate reverse leakage currents of first samples (corresponding to the semiconductor device according to Embodiment 1 except for the Schottky gate electrode) undergoing annealing processing after formation of Ni/Au electrode structures. Black triangles indicate reverse leakage currents of second samples (corresponding to the semiconductor device according to Embodiment 1) undergoing annealing processing after formation of Ni single-electrodes. The duration of annealing processing performed with respect to each sample is five minutes.

When reverse leakage currents of the first samples (white circles) are compared with one another, as for annealing processing performed at a temperature of approximately 500° C. or below, a reverse leakage current is suppressed more in a first sample undergoing annealing processing than in a first sample not undergoing annealing processing, and the suppression effects increase with increasing temperature of annealing processing. As shown in FIG. 6, however, the reverse leakage current of the first sample reaches its minimum at a temperature of approximately 500° C., and increases when temperature of annealing processing becomes 500° C. or above, leading to deterioration of electrical characteristics.

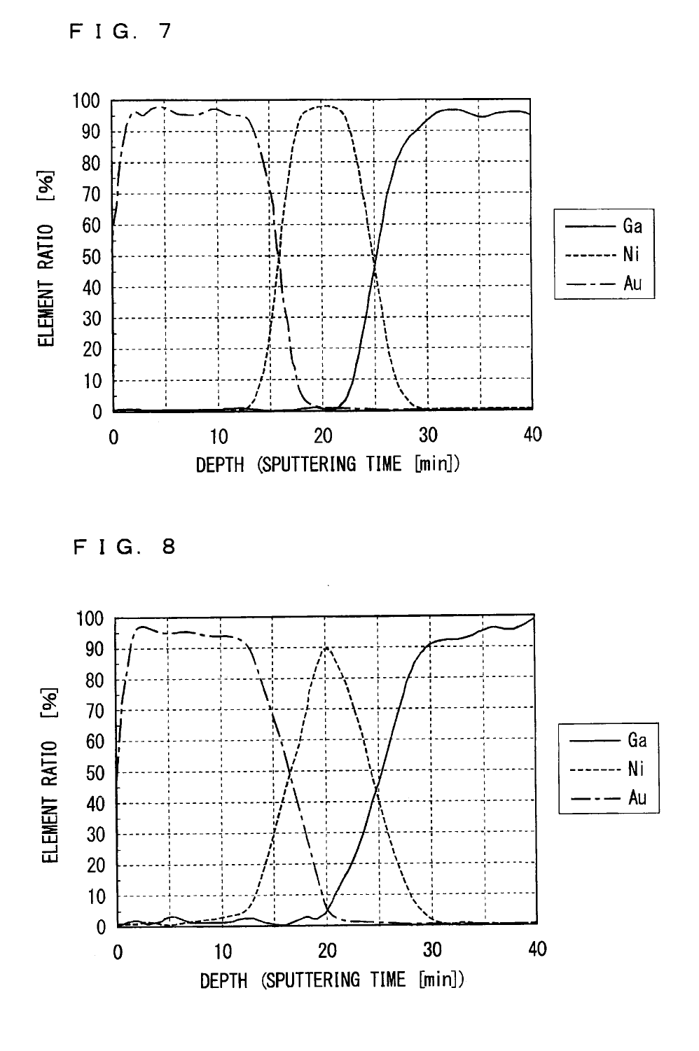

This is presumably because a layer structure between the Ni/Au electrode structure and the surface of the Alₓ₁Ga₁₋ₓ₁N (0≦x1≦1) barrier layer 4 varies depending on temperature of annealing processing. To support the presumption, a difference in element ratio in a depth direction of an Ni/Au electrode structure depending on the temperature of annealing processing is shown in FIGS. 7, 8, and 9. After a plurality of samples, i.e., first samples, are produced by forming Ni/Au electrode structures (an Ni layer and an Au layer have thicknesses of 50 nm and 170 nm, respectively) on Al_{0.17}Ga_{0.83}N layers (corresponding to the Alₓ₁Ga₁₋ₓ₁N (0≦x1≦1) barrier layer 4 where a value of x1 is 0.17), annealing processing is performed with respect to the produced samples at different temperatures. Each of the samples is then etched through Ar sputter processing and evaluated by X-ray photoelectron spectroscopy (XPS) to identify an element ratio in a depth direction. In FIGS. 7-9, a direction of passage of a sputtering time shown on the horizontal axis thus corresponds to the depth direction of each sample.

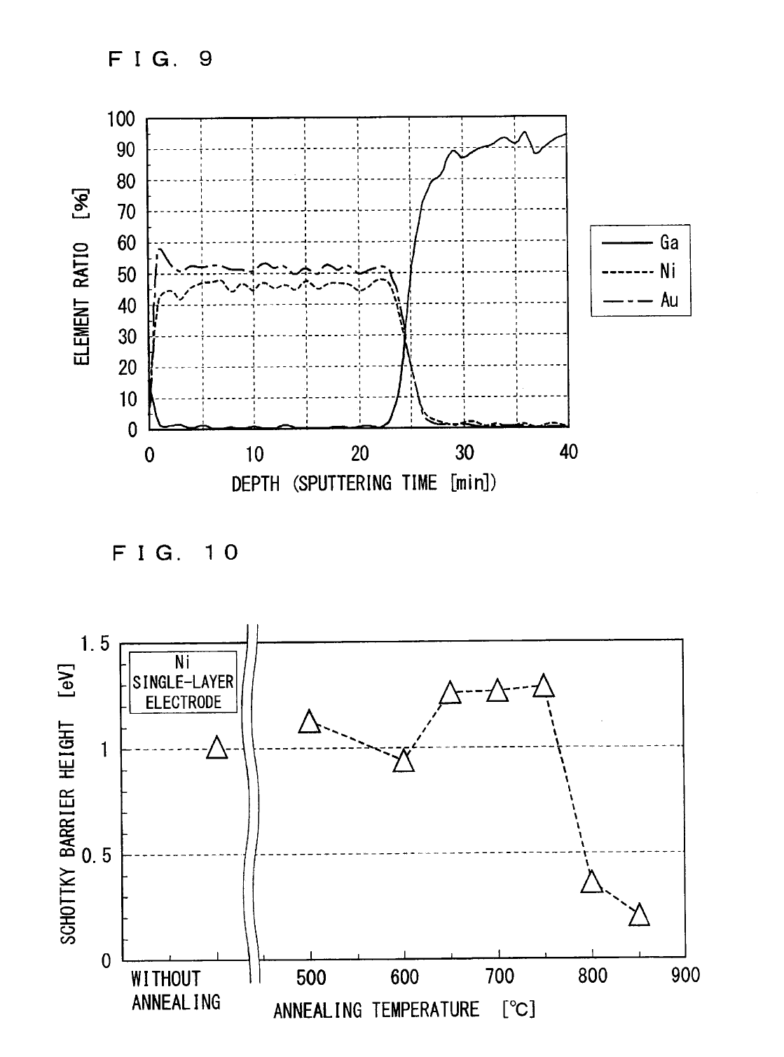

FIG. 7 shows results of evaluation of a sample without annealing processing, FIG. 8 shows results of evaluation of a sample undergoing annealing processing at a temperature of 500° C. for five minutes, and FIG. 9 shows results of evaluation of a sample undergoing annealing processing at a temperature of 700° C. for five minutes. As shown in FIG. 8, in the sample undergoing annealing processing at a temperature of 500° C., compared with the sample without annealing processing, some diffusion of elements is observed between the Al_{0.17}Ga_{0.83}N layer and the Ni layer, and between the Ni layer and the Au layer, but diffusion of elements is not observed between the Al_{0.17}Ga_{0.83}N layer and the Au layer. In the sample undergoing annealing processing at a temperature of 700° C., however, the Ni/Au layer structure is lost through alloying of the Ni layer and the Au layer, and, as a result, diffusion of Au into the Al_{0.17}Ga_{0.83}N layer can be observed.

When the change in reverse leakage currents (FIG. 6) is considered in light of the results of analysis of the element ratio focusing on the interface of the Schottky junction (FIGS. 7-9), a reduction in reverse leakage currents with increasing temperature of annealing processing at a temperature below a fixed temperature is estimated to be attributable to formation (maintenance) of a reaction layer between the Al_{0.17}Ga_{0.83}N layer and the Ni layer. On the other hand, an increase in reverse leakage currents with increasing temperature of annealing processing at the fixed temperature or above is estimated to be attributable to a loss of the above-mentioned reaction layer due to Au reaching the Al_{0.17}Ga_{0.83}N layer (formation of a contact between a semiconductor and Au).

Next, the inventors performed verification using Ni single-electrodes to verify that the reverse leakage current reduction effects in annealing processing were produced by the reaction layer formed (maintained) between the Al_{0.17}Ga_{0.83}N layer and the Ni layer, and to estimate a range of temperature suitable for obtaining the reverse leakage current reduction effects.

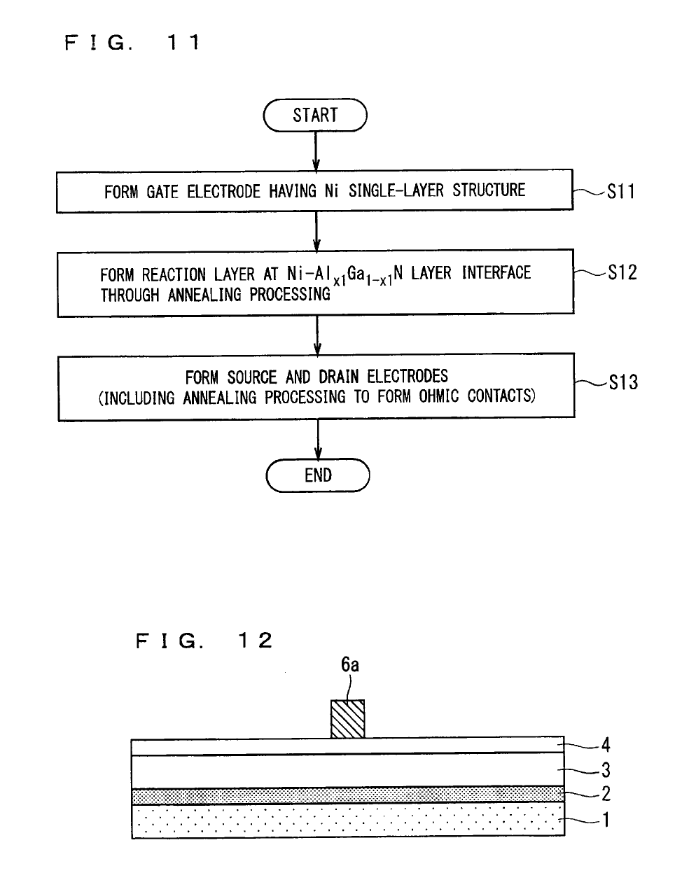

FIG. 10 shows the height of the Schottky barrier dependent on temperature of annealing processing in samples produced by forming gate electrodes formed of the Ni single-electrodes on Al_{0.17}Ga_{0.83}N layers, as with the samples described above. The duration of annealing processing performed with respect to each sample is five minutes.

FIG. 10 shows that the Schottky barrier is higher in structures in which annealing processing is performed at temperatures of 650° C., 700° C., and 750° C. than in structures in which annealing processing is performed under other temperature conditions. These results are consistent with the reverse leakage current reduction effects shown by black triangles in FIG. 6, and show that the effects are obtained by the reduction in reverse leakage currents. Furthermore, a change in height of the Schottky barrier with temperature of annealing processing shows that a change (i.e., formation of the reaction layer) is caused at an interface between the Al_{0.17}Ga_{0.83}N layer and the Ni single-electrode. It was verified that the reverse leakage current reduction effects in annealing processing were attributed to the reaction layer formed (maintained) between the Al_{0.17}Ga_{0.83}N layer and the Ni layer. It was also found that a temperature range in which the highest effects are obtained is 650° C. to 750° C. inclusive.

In summary, when annealing processing is performed at a temperature of 500° C. or above in the first samples undergoing the annealing processing after formation of the Ni/Au electrode structures, the reaction layers are lost and reverse leakage currents increase, leading to deterioration of electrical characteristics. In contrast, in the manufacturing method according to Embodiment 1, after formation of the gate electrode 6a having the Ni single-layer structure on the Alₓ₁Ga₁₋ₓ₁N (0≦x1≦1) barrier layer 4, annealing processing is performed with respect to the gate electrode 6a at a temperature of 500° C. to 750° C. inclusive under a nitrogen atmosphere. According to such a structure, there is no possibility that Au comes into contact with the Alₓ₁Ga₁₋ₓ₁N (0≦x1≦1) barrier layer 4. As a result, the reaction layer 7 can be formed (maintained) through annealing processing performed at a high temperature (a temperature that is appropriate for the reaction layer 7 between the Alₓ₁Ga₁₋ₓ₁N (0≦x1≦1) barrier layer 4 and Ni of the gate electrode 6a). That is to say, the reaction layer 7 that contains Ni of the gate electrode 6a and an element contained in the Alₓ₁Ga₁₋ₓ₁N (0≦x1≦1) barrier layer 4, but does not contain a metal element (e.g., Au) diffusing from a metal layer 8 described later can be formed (maintained), for example. Consequently, reverse leakage currents I [A/cm²] can be reduced as shown in FIG. 6.

In the manufacturing method including formation of a gate electrode having an Ni/Au structure, a process involving annealing processing at a temperature of 500° C. or above (e.g., a processing of forming a Ti/Au ohmic electrode that preferably undergoes annealing processing at a temperature of at least approximately 600° C.) is required to be performed before a process of forming the gate electrode so as not to increase reverse leakage currents.

In contrast, in Embodiment 1, as described above, an increase in reverse leakage currents can be suppressed even if the process involving annealing processing at a temperature of 500° C. or above is performed after the process of forming the gate electrode, and thus flexibility in the manufacturing method can be increased. Even in the method of manufacturing the semiconductor device according to Embodiment 1, annealing processing performed at a temperature above 750° C. causes deterioration of Schottky characteristics, leading to an increase in reverse leakage currents.

Elements constituting the reaction layer 7 may contain elements, such as O (oxygen), H (hydrogen), and C (carbon), caused through natural oxidization and adhesion of moisture, which inevitably occur in the atmosphere. For example, when an epitaxial substrate including an Alₓ₁Ga₁₋ₓ₁N (x1≈0.20) barrier layer as its topmost layer is exposed to the atmosphere, an approximately 14% of O (oxygen) content and an approximately 13% of C (carbon) content can be detected from an uppermost surface layer (a layer between a surface and a portion at a depth of 5 nm from the surface) through analysis of a surface of the barrier layer by X-ray photoelectron spectroscopy (XPS). The reaction layer 7 can contain the same types of elements at an equivalent level, but this has no immediate effects on the semiconductor device according to Embodiment 1. The reaction layer 7 may thus contain these elements at the same level. The elements and values described herein are just examples, and are not absolute.

### Embodiment 2

The semiconductor device according to Embodiment 2 of the present invention has a similar structure (FIG. 1) to the semiconductor device according to Embodiment 1. Components of the semiconductor device according to Embodiment 2 that are the same as or similar to those described above bear the same reference signs, and description is made mainly on differences below.

<Manufacturing Method>

FIG. 11 is a flow chart showing a method of manufacturing the semiconductor device according to Embodiment 2. The method of manufacturing the semiconductor device is described below, in an order of steps shown in FIG. 11.

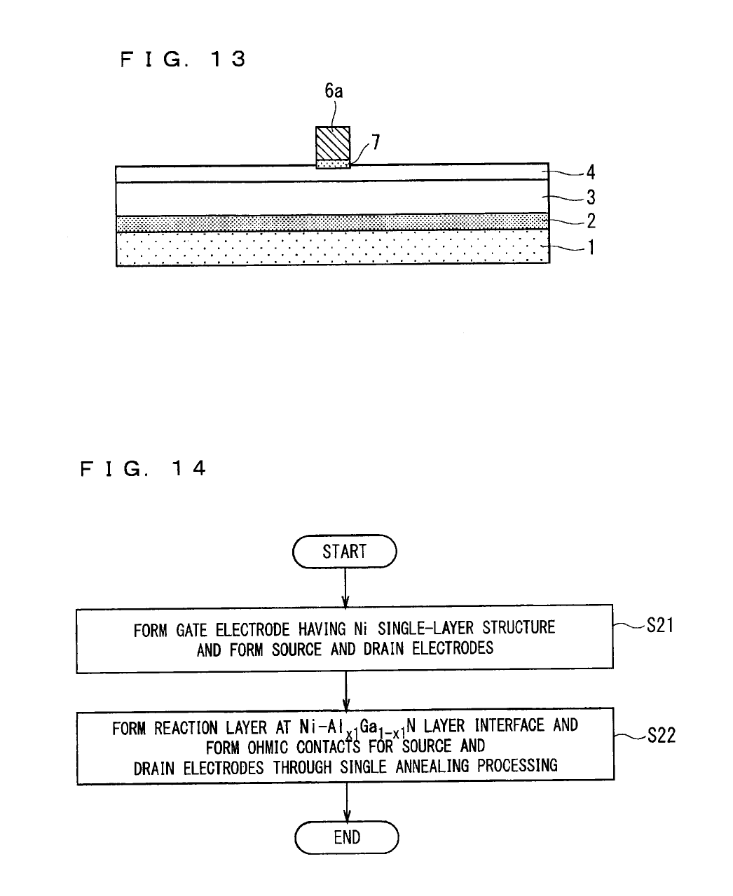

In step S11, as shown in FIG. 12, the buffer layer 2, the GaN channel layer 3, and the Alₓ₁Ga₁₋ₓ₁N (0≦x1≦1) barrier layer 4 are formed on the SiC substrate 1 in the stated order as in Embodiment 1.

In the same step S11, the gate electrode 6a that forms a Schottky junction with the surface of the Alₓ₁Ga₁₋ₓ₁N (0≦x1≦1) barrier layer 4 and has the Ni single-layer structure is formed on the surface of the Alₓ₁Ga₁₋ₓ₁N (0≦x1≦1) barrier layer 4 before formation of the source and drain electrodes 5.

In Embodiment 2, the thickness of the gate electrode 6a in its height direction is 200 nm, but the gate electrode 6a may have any other thickness as long as the gate electrode 6a functions as a Schottky gate electrode. In Embodiment 2, the gate electrode 6a is formed by a deposition lift-off method using a resist pattern having a double-layer structure, but other methods may be used as long as the gate electrode 6a having the Ni single-layer structure can be formed as in Embodiment 1.

Next, in step S12, annealing processing is performed with respect to the gate electrode 6a at a temperature of 500° C. to 750° C. inclusive under a nitrogen atmosphere. Conditions of the annealing processing are that the annealing processing is performed at a temperature of 500° C. to 750° C. inclusive for five minutes under an inert gas atmosphere, for example. The annealing processing is preferably performed at a temperature of 650° C. to 750° C. inclusive for five minutes under a nitrogen atmosphere. As a result, as shown in FIG. 13, the reaction layer 7 is formed between the above-mentioned surface of the Alₓ₁Ga₁₋ₓ₁N (0≦x1≦1) barrier layer 4 and the gate electrode 6a.

Next, in step S13, electrodes that become the source and drain electrodes 5 are formed in regions, on the surface of the Alₓ₁Ga₁₋ₓ₁N (0≦x1≦1) barrier layer 4, other than a region in which the gate electrode 6a is to be formed. Annealing processing is then performed at a temperature of 750° C. or below to form, from the electrodes, the source and drain electrodes 5 (ohmic electrodes) that form ohmic contacts with the surface of the Alₓ₁Ga₁₋ₓ₁N (0≦x1≦1) barrier layer 4 as shown in FIG. 1.

In Embodiment 2, the electrodes that become the source and drain electrodes 5 have Ti/Al/Ti/Au (having thicknesses of 20 nm, 100 nm, 40 nm, and 30 nm, respectively) ohmic electrode structures. The source and drain electrodes 5, however, may have other electrode structures (electrodes) as long as their electrode structures (electrodes) can provide ohmic contacts with the Alₓ₁Ga₁₋ₓ₁N (0≦x1≦1) barrier layer 4 as in Embodiment 1.

In Embodiment 2, the electrodes that become the source and drain electrodes 5 are formed by a deposition lift-off method using a resist pattern having a double-layer structure. However, other methods may be used as long as desired ohmic contacts can be provided through annealing processing performed at a temperature of 750° C. or below as in Embodiment 1.

<Effects>

In the method of manufacturing the first samples described in Embodiment 1, i.e., in the manufacturing method of forming the gate electrodes through annealing processing after formation of the Ni/Au electrode structures, a process involving annealing processing at a temperature of 500° C. or above cannot be performed after formation of the gate electrodes. This results in not only restrictions placed on an order of steps of the process but also a process history (a process damage) that inevitably occurs due to exposure of a gate formation region of the Alₓ₁Ga₁₋ₓ₁N (0≦x1≦1) barrier layer 4 to a high-temperature environment and to the outside until the gate electrode 6a is formed.

In contrast, in the method of manufacturing the semiconductor device according to Embodiment 2, the reaction layer 7 can be formed (maintained) through high-temperature annealing processing (annealing processing performed at a temperature that is appropriate for the reaction layer 7 between the Alₓ₁Ga₁₋ₓ₁N (0≦x1≦1) barrier layer 4 and Ni of the gate electrode 6a). Consequently, the reverse leakage currents I can be reduced, and flexibility in the manufacturing method can be increased as in Embodiment 1. Furthermore, since the gate electrode 6a is formed at a relatively early stage, the gate formation region is not exposed to a high-temperature environment, such as annealing processing performed to form the source and drain electrodes 5. The process history (the process damage) in the gate formation region can be suppressed.

### Embodiment 3

The semiconductor device according to Embodiment 3 of the present invention has a similar structure (FIG. 1) to the semiconductor device according to Embodiment 1. Components of the semiconductor device according to Embodiment 3 that are the same as or similar to those described above bear the same reference signs, and description is made mainly on differences below.

<Manufacturing Method>

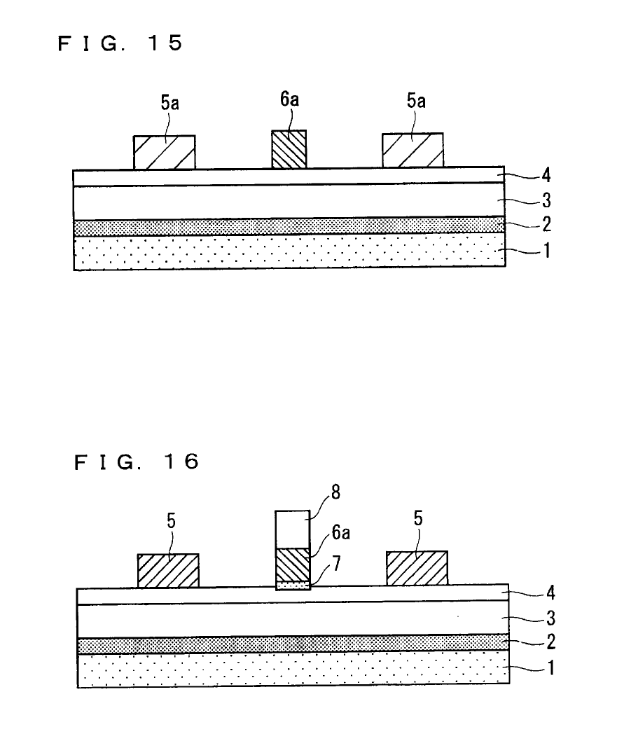

FIG. 14 is a flow chart showing a method of manufacturing the semiconductor device according to Embodiment 3. The method of manufacturing the semiconductor device is described below, in an order of steps shown in FIG. 14,

In step S21, as shown in FIG. 15, the buffer layer 2, the GaN channel layer 3, and the Alₓ₁Ga₁₋ₓ₁N (0≦x1≦1) barrier layer 4 are formed on the SiC substrate 1 in the stated order as in Embodiment 1.

Next, in the same step S21, electrodes 5a that become the source and drain electrodes 5 are formed in regions, on the surface of the Alₓ₁Ga₁₋ₓ₁N (0≦x1≦1) barrier layer 4, other than a region in which the gate electrode 6a is to be formed. In Embodiment 3, the electrodes that become the source and drain electrodes 5 have Ti/Al/Ti/Au (having thicknesses of 20 nm, 100 nm, 40 nm, and 30 nm, respectively) ohmic electrode structures. The source and drain electrodes 5, however, may have other electrode structures (electrodes) as long as their electrode structures (electrodes) can provide ohmic contacts with the Alₓ₁Ga₁₋ₓ₁N (0≦x1≦1) barrier layer 4 as in Embodiment 1.

In Embodiment 3, the electrodes that become the source and drain electrodes 5 are formed by a deposition lift-off method using a resist pattern having a double-layer structure. However, other methods may be used as long as desired ohmic contacts can be provided through annealing processing performed at a temperature of 500° C. to 750° C. inclusive as in Embodiment 1.

Next, in the same step S21, the gate electrode 6a that forms a Schottky junction with the surface of the Alₓ₁Ga₁₋ₓ₁N (0≦x1≦1) barrier layer 4 and has the Ni single-layer structure is formed on the surface of the Alₓ₁Ga₁₋ₓ₁N (0≦x1≦1) barrier layer 4 without performing annealing processing. In Embodiment 3, the thickness of the gate electrode 6a in its height direction is 200 nm, but any other thickness may be selected as in Embodiment 2. In Embodiment 3, the gate electrode 6a is formed by a deposition lift-off method using a resist pattern having a double-layer structure, but other methods may be used as long as the gate electrode 6a having the Ni single-layer structure can be formed as in Embodiment 2.

In Embodiment 3, the gate electrode 6a is formed after formation of the electrodes 5a, but the electrodes 5a may be formed after formation of the gate electrode 6a.

Next, in step S22, annealing processing at a temperature of 500° C. to 750° C. inclusive (preferably annealing processing at a temperature of 650° C. to 750° C. inclusive) is performed with respect to the gate electrode 6a under a nitrogen atmosphere. As a result, as shown in FIG. 1, the reaction layer 7 is formed between the above-mentioned surface of the Alₓ₁Ga₁₋ₓ₁N (0≦x1≦1) barrier layer 4 and the gate electrode 6a, and the source and drain electrodes 5 that form ohmic contacts with the surface of the Alₓ₁Ga₁₋ₓ₁N (0≦x1≦1) barrier layer 4 are formed from the electrodes 5a.

In Embodiment 3, annealing processing is performed to simultaneously form ohmic junctions and the reaction layer 7, and thus any temperature (condition) in a range (e.g., a temperature range of 500° C. to 750° C. inclusive under an inert gas atmosphere) that allows for simultaneous formation can be applied. When the highest priority is given to formation of the reaction layer 7, it is desirable to perform annealing processing at a temperature of 700° C. for five minutes under a nitrogen atmosphere.

<Effects>

In Embodiment 3, similar effects to those obtained in Embodiment 2 can be obtained. In addition, since annealing processing to form ohmic electrodes (the source and drain electrodes 5) and annealing processing to form the reaction layer 7 are performed simultaneously, the number of times of high-temperature heat treatment is reduced, resulting in a reduction of a process damage. Furthermore, a manufacturing process is expected to be simplified.

### Embodiment 4

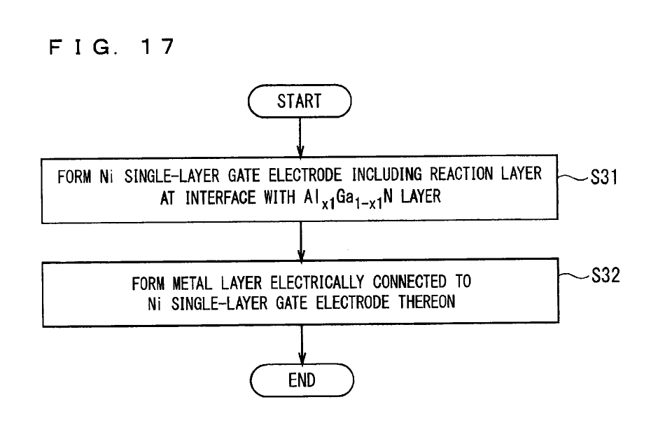

FIG. 16 is a cross section showing the structure of a semiconductor device according to Embodiment 4 of the present invention. The semiconductor device shown in FIG. 16 is obtained by adding the metal layer 8 to any of the semiconductor devices described in Embodiments 1-3. Components of the semiconductor device according to Embodiment 4 that are the same as or similar to those described above bear the same reference signs, and description is made mainly on differences below.

<Manufacturing Method>

FIG. 17 is a flow chart showing a method of manufacturing the semiconductor device according to Embodiment 4. The method of manufacturing the semiconductor device is described below, in an order of steps shown in FIG. 17.

In step S31, the semiconductor device shown in FIG. 1 is formed by any of the manufacturing methods described in Embodiments 1-3.

Next, in step S32, as shown in FIG. 16, at least one metal layer 8 that is electrically connected to the gate electrode 6a and contains Au is formed on the gate electrode 6a. The method of forming the metal layer 8 is not limited as long as the metal layer 8 is electrically connected to the gate electrode 6a having the Ni single-layer structure, but the metal layer 8 is preferably formed by a deposition lift-off method using a resist pattern or a sputter lift-off method that allow for fine patterning. Alternatively, the metal layer 8 may be formed on the gate electrode 6a by using another process such as a plating process.

The metal layer 8 should be at least one metal layer containing Au, and is preferably an Au single-layer, which has the simplest structure. The structure of the metal layer 8, however, is not limited to the above-mentioned structures, and may be a multilayer structure including an Au layer, such as a Pt (platinum)/Au structure, an Nb/Au structure, a Ti/Au structure, or an Ni/Au structure, to suppress diffusion of Au in the metal layer in a high-temperature environment, for example. In Embodiment 4, the thickness of the metal layer 8 is 200 nm, but another thickness may be selected depending on a formation method and desired characteristics.

<Effects>

In Embodiment 4 as described above, similar effects to those obtained in Embodiment 1 and the like can be obtained. Since Au contained in the metal layer 8 has lower resistivity than Ni, gate resistance can be reduced compared to the semiconductor devices according to Embodiments 1-3, and a voltage drop of an input signal caused by the gate resistance can be suppressed.

The gate electrode 6a having the Ni single-layer structure and the metal layer 8 formed on the gate electrode 6a are described above as different components, but they may not be different components. For example, the gate electrode 6a may include the metal layer 8 as an upper layer thereof. That is to say, the gate electrode 6a may have a laminated structure in which at least a lowermost layer substantially is Ni, and in which a layer on or above Ni of the lowermost layer is a metal layer that is similar to the metal layer 8. With this structure, similar effects to those obtained above can be obtained.

It should be noted that the present invention can be implemented by freely combining the embodiments or by appropriately making modification or omission to each of the embodiments without departing from the scope of the present invention.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor layer that is an Alₓ₁Ga₁₋ₓ₁N (0≦x1≦1) barrier layer or an Alₓ₂Ga₁₋ₓ₂N (0≦x2≦1) cap layer formed on said barrier layer;
a gate electrode that is disposed on a surface of said semiconductor layer, and forms a Schottky junction with the surface of said semiconductor layer, at least a lowermost layer of said gate electrode substantially being Ni; and
a reaction layer that is provided at an interface of said Schottky junction, and contains Ni of the lowermost layer of said gate electrode and an element contained in said semiconductor layer, but does not contain a metal element diffusing from a metal layer on or above Ni of the lowermost layer of said gate electrode.

2. A method of manufacturing a semiconductor device, the method comprising the steps of:
(a) forming a gate electrode on a surface of a semiconductor layer that is an Alₓ₁Ga₁₋ₓ₁N (0≦x1≦1) barrier layer or an Alₓ₂Ga₁₋ₓ₂N (0≦x2≦1) cap layer formed on said barrier layer, the gate electrode forming a Schottky junction with the surface of said semiconductor layer, and having an Ni single-layer structure; and
(b), after said step (a), performing annealing processing with respect to said gate electrode at a temperature of 500° C. to 750° C. inclusive under a nitrogen atmosphere to form a reaction layer between said surface of said semiconductor layer and said gate electrode, the reaction layer containing Ni of said gate electrode and an element contained in said semiconductor layer.

3. The method of manufacturing the semiconductor device according to claim 2, wherein
in said step (b), said annealing processing is performed at a temperature of 650° C. to 750° C. inclusive.

4. The method of manufacturing the semiconductor device according to claim 2, the method further comprising the steps of:
(c), before said step (a), forming an electrode in a region, on said surface of said semiconductor layer, other than a region in which said gate electrode is to be formed; and
(d), after said step (c) and before said step (a), performing annealing processing to form an ohmic contact between said semiconductor layer and said electrode.

5. The method of manufacturing the semiconductor device according to claim 2, the method further comprising the steps of:
(c), after said step (b), forming an electrode in a region, on said surface of said semiconductor layer, other than a region in which said gate electrode is to be formed; and
(d), after said step (c), performing annealing processing at a temperature of 750° C. or below to form an ohmic contact between said semiconductor layer and said electrode.

6. The method of manufacturing the semiconductor device according to claim 2, the method further comprising the step of
(c), before said step (b), forming an electrode in a region, on said surface of said semiconductor layer, other than a region in which said gate electrode is to be formed, wherein
in said step (b), said annealing processing is performed to form said reaction layer and to form an ohmic contact between said semiconductor layer and said electrode.

7. The method of manufacturing the semiconductor device according to claim 2, the method further comprising the step of
(e), after said step (b), forming, on said gate electrode, at least one metal layer that is electrically connected to said gate electrode and contains Au.

8. The method of manufacturing the semiconductor device according to claim 5, the method further comprising the step of
(e), after said step (d), forming, on said gate electrode, at least one metal layer that is electrically connected to said gate electrode and contains Au.
